(19) United States
(12) Patent Application Publication
(10) Pub. No.: US 2026/0029493 A1
(43) Pub. Date: Jan. 29, 2026

(54) MAGNETIC PARTICLE IMAGING SYSTEM, MAGNETIC PARTICLE IMAGING METHOD, AND NON-TRANSITORY COMPUTER-READABLE STORAGE MEDIUM STORING MAGNETIC PARTICLE IMAGING PROGRAM

(71) Applicant: Mitsubishi Electric Corporation, Tokyo (JP)

(72) Inventor: Kazuki YAMAUCHI, Chiyoda-ku, Tokyo (JP)

(73) Assignee: Mitsubishi Electric Corporation, Tokyo (JP)

(21) Appl. No.: 18/996,342

(22) PCT Filed: Aug. 23, 2022
(86) PCT No.: PCT/JP2022/031728

§ 371 Date: Jan. 17, 2025

(51) Int. Cl. G01R 33/12; G01R 33/00

(52) U.S. Cl. CPC G01R 33/1276; G01R 33/0023

(57) ABSTRACT

A processor calculates a system function by a first deconvolution operation based on a set of a first detection signal obtained while a calibration sample is disposed in an examination region and a numerical model of a spatial distribution of magnetic particles included in the calibration sample. The processor obtains a spatial distribution of magnetic particles included in an examination sample by a second deconvolution operation based on a set of a second detection signal obtained while the examination sample is disposed in the examination region and the system function.

### TECHNICAL FIELD

The present disclosure relates to a magnetic particle imaging system, a magnetic particle imaging method, and a magnetic particle imaging program.

### BACKGROUND ART

A magnetic particle imaging system has conventionally been known. The magnetic particle imaging system comprises a selection means for generating a magnetic selection field having a low magnetic field region and a high magnetic field region in an examination region, a driving means for changing a relative positional relationship of two regions in the examination region with respect to magnetic particles, an excitation means for applying a magnetic excitation field to change magnetization of the magnetic particles, and a reception means for receiving a change in the magnetization of the magnetic particles as a detection signal.

The value of the detection signal of the magnetic particle imaging system is a value obtained by convolution integral of the spatial distribution of the magnetic particles with a system function, and accordingly, imaging the spatial distribution of the magnetic particles from the detection signal involves image reconstruction involving deconvolution of the system function.

The system function includes the magnetic particles' magnetization curve and information of the system (i.e., the selection means, the driving means, the excitation means, and the reception means), and generally, data of the system function is obtained in advance of an examination for each selection of particles to be used in the examination and each setting condition of the system. As a method for obtaining the system function, a method using actual measurement is known.

In the method based on actual measurement, a value measured while a small point-like calibration sample is moved from one point to another point in an examination region is obtained as the system function. The calibration sample includes magnetic particles in a small amount, and accordingly, obtaining a sufficient SN ratio requires taking time for the measurement at each point. As a result, obtaining the system function requires an enormous amount of time.

To address this issue, PTL 1 uses a method through numerical calculation. PTL 1 utilizes a spatial symmetry that a system function theoretically has. For example, when the system function has a distribution symmetric with respect to two axes, a point-like calibration sample is disposed and moved in only a one-fourth region to obtain signal strength at each location. Thereafter, a measurement signal is replicated to match the symmetry of the system function to create the system function.

### CITATION LIST

### Patent Literature

PTL 1: Japanese National Patent Publication No. 2012-510847

### SUMMARY OF INVENTION

### Technical Problem

However, the method described in PTL 1 cannot handle the system function's skewness caused by a manufacturing error. This results in an artifact produced in a reconstructed image, reduced spatial resolution, reduced quantitativeness etc., and hence the reconstructed image having degraded image quality.

Therefore, an object of the present disclosure is to provide a magnetic particle imaging system, a magnetic particle imaging method, and a magnetic particle imaging program capable of obtaining a system function in a shorter period of time than a method by actual measurement and also producing a high-quality reconstructed image.

### Solution to Problem

According to the present disclosure, a magnetic particle imaging system to image a spatial distribution of magnetic particles in an examination region comprises: a selector to generate a magnetic selection field having a spatial pattern of magnetic field strength to form in the examination region a first partial region having a low magnetic field strength and a second partial region having a higher magnetic field strength; an exciter to provide a magnetic excitation field to change magnetization of the magnetic particles present in the magnetic selection field; a receiver to receive as a detection signal a change in magnetization of the magnetic particles excited by the magnetic excitation field; and a processor. The detection signal is represented by a convolution of a spatial distribution of the magnetic particles and a system function. The processor calculates the system function by a first deconvolution operation based on a data set of a first detection signal obtained while a calibration sample is disposed in the examination region and a numerical model of a spatial distribution of magnetic particles included in the calibration sample, and the processor obtains a spatial distribution of magnetic particles included in an examination sample by a second deconvolution operation based on a data set of a second detection signal obtained while the examination sample is disposed in the examination region and the system function.

According to the present disclosure, a magnetic particle imaging method for imaging a spatial distribution of magnetic particles in an examination region comprises: generating by a selector a magnetic selection field having a spatial pattern of magnetic field strength to form in the examination region a first partial region having a low magnetic field strength and a second partial region having a higher magnetic field strength; providing by an exciter a magnetic excitation field to change magnetization of the magnetic particles present in the magnetic selection field; and receiving by a receiver as a detection signal a change in magnetization of the magnetic particles excited by the magnetic excitation field. The detection signal is represented by a convolution of a spatial distribution of the magnetic particles and a system function. The magnetic particle imaging method includes: calculating by a processor the system function by a first deconvolution operation based on a data set of a first detection signal obtained while a calibration sample is disposed in the examination region and a numerical model of a spatial distribution of magnetic particles included in the calibration sample; and obtaining by the processor a spatial distribution of magnetic particles included in an examination sample by a second deconvolution operation based on a data set of a second detection signal obtained while the examination sample is disposed in the examination region and the system function.

According to the present disclosure, in a magnetic particle imaging program for use in a magnetic particle imaging system to image a spatial distribution of magnetic particles in an examination region, the magnetic particle imaging system generates a magnetic selection field having a spatial pattern of magnetic field strength to form in the examination region a first partial region having a low magnetic field strength and a second partial region having a higher magnetic field strength, provides a magnetic excitation field to change magnetization of the magnetic particles present in the magnetic selection field, and receives as a detection signal a change in magnetization of the magnetic particles excited by the magnetic excitation field. The magnetic particle imaging system comprises a processor. The detection signal is represented by a convolution of a spatial distribution of the magnetic particles and a system function. The magnetic particle imaging program causes the processor to preform: calculating the system function by a first deconvolution operation based on a data set of a first detection signal obtained while a calibration sample is disposed in the examination region and a numerical model of a spatial distribution of magnetic particles included in the calibration sample; and obtaining a spatial distribution of magnetic particles included in an examination sample by a second deconvolution operation based on a data set of a second detection signal obtained while the examination sample is disposed in the examination region and the system function.

### Advantageous Effects of Invention

According to the present disclosure, a system function can be obtained in a short period of time and a reconstructed image can be produced with high quality.

### BRIEF DESCRIPTION OF DRAWINGS

FIG. 1 is a diagram showing an example of a general configuration of a magnetic particle imaging system.

FIG. 2 is a diagram illustrating an example of a hardware configuration of an information processing device 11.

FIG. 3 is a flowchart of a procedure of a magnetic particle imaging method according to an embodiment.

FIG. 4 is a flowchart of a procedure of measuring a calibration sample in step S104 of FIG. 3.

FIG. 5 is a diagram illustrating an example of disposing a calibration sample.

FIG. 6 is a flowchart of a procedure of a subroutine of generating a system function (or a first deconvolution operation) in step S206 of FIG. 4.

FIG. 7 is a flowchart of a procedure of diagnostic measurement (or examination sample measurement) in step S107 of FIG. 3.

FIG. 8 is a flowchart of a procedure of a spatial distribution imaging process (or a second deconvolution operation) in step S406 of FIG. 7.

FIG. 9 is a flowchart of a procedure of measuring a calibration sample according to PTL 1.

FIG. 10 is a diagram showing an example of disposing a calibration sample according to PTL 1.

FIG. 11 is a flowchart of a procedure of a system function generating subroutine according to PTL 1.

### DESCRIPTION OF EMBODIMENTS

Hereinafter, an embodiment will be described with reference to the drawings.

### First Embodiment

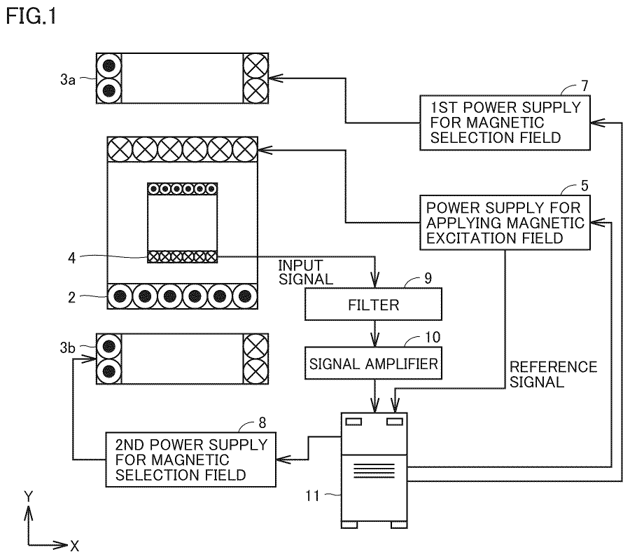

FIG. 1 is a diagram showing an example of a general configuration of a magnetic particle imaging system.

The magnetic particle imaging system comprises an exciter 2, a first selector 3a, a second selector 3b, a receiver 4, a power supply 5 for applying a magnetic excitation field, a first power supply 7 for magnetic selection field, a second power supply 8 for magnetic selection field, a filter 9, a signal amplifier 10, and an information processing device 11.

First selector 3a and second selector 3b generate a magnetic selection field having a spatial pattern of magnetic field strength to form a first partial region having a low magnetic field strength and a second partial region having a higher magnetic field strength in an examination region in which an analyte is disposed.

This limits those of magnetic particles present in the examination region which can contribute to a measurement signal to a region in a vicinity of the first partial region. In the first partial region, a region with a magnetic field strength having a value close to zero, in particular, is referred to as a field free region (FFR). For example, field free region FER is also referred to as a field free point (FFP), a field free line (FFL), or a field free plane, depending on the shape. The FFL may have a field free region extending in one direction and may for example be in the form of a rectangle, in which case, it has a longer side in a direction in which it extends, or an ellipse. For example, a field free plane and an FFL have a larger region that can contribute to the signal than an FFP, and are advantageous in that an SN ratio sufficient for measurement and image reconstruction can be obtained in a short period of time.

First selector 3a includes a first electromagnet. Second selector 3b includes a second electromagnet. The first electromagnet and the second electromagnet are disposed opposite to each other to generate magnetic fields in opposite directions in the examination region. The first electromagnet is connected to first power supply 7 for magnetic selection field. The second electromagnet is connected to second power supply 8 for magnetic selection field. First power supply 7 for magnetic selection field passes a current to the first electromagnet and second power supply 8 for magnetic selection field passes a current to the second electromagnet to thereby generate a magnetic selection field. Changing in magnitude the currents from first power supply 7 for magnetic selection field and second power supply 8 for magnetic selection field can change a positional relationship of the magnetic selection field (more specifically, the first partial region and the second partial region) relative to the magnetic particles (or cause electrical movement).

For example, changing a balance between the current for the first electromagnet and that for the second electromagnet allows field free region FFR in the examination region to be positionally moved in a translational direction or a rotational direction. The first partial region (field free region FFR, in particular) is thus driven and scanned in a scan region. How the magnetic selection field is generated is not limited to an electromagnet. The first electromagnet and the second electromagnet may be replaced with two permanent magnets disposed opposite to each other or a combination of a permanent magnet and an electromagnet. Furthermore, how a magnetic field (in this example, field free region FFR) is scanned is not limited as described above. For example, the magnetic field may be driven and scanned by physical movement of first selector 3a and second selector 3b or a combination of electrical movement and physical movement thereof. Alternatively, the magnetic field may be positionally fixed and the analyte may be moved to scan the magnetic field relative to the analyte.

Exciter 2 applies a magnetic excitation field to change magnetization of magnetic particles present in a magnetic selection field of an examination region in which a calibration sample, or an examination sample or a similar analyte is disposed. The calibration sample is used to determine the system function and is a sample having a known magnetic particle distribution. The examination sample is a sample having s magnetic particle distribution to be examined.

For example, exciter 2 includes a coil connected to power supply 5 for applying a magnetic excitation field. When power supply 5 for applying a magnetic excitation field passes an AC current to the coil, an AC magnetic field is applied as a magnetic excitation field to the examination region in which the analyte is disposed.

When the magnetic excitation field is applied to the analyte, the magnetic particles included in the analyte generate a magnetic signal of a fundamental wave having the same frequency as the magnetic excitation field and a magnetic signal of a harmonic higher in order than that. The magnetic particles are modified with a substance such as a protein that binds through an antigen-antibody reaction to a target substance contained in the analyte.

Receiver 4 receives as a detection signal a change in magnetization of magnetic particles excited by the magnetic excitation field. Receiver 4 for example includes a coil. Receiver 4 may be a hall element, a magnetoresistive element (an AMR (anisotropic magneto resistive) element, an SMR (semiconductor magneto resistive) element, a TMR (tunnel magneto resistive) element and the like), an MI (magneto impedance) sensor, or the like, that can detect a varying magnetic field. The detection signal is input to information processing device 11 via, for example, a noise removal filter 9 and signal amplifier 10.

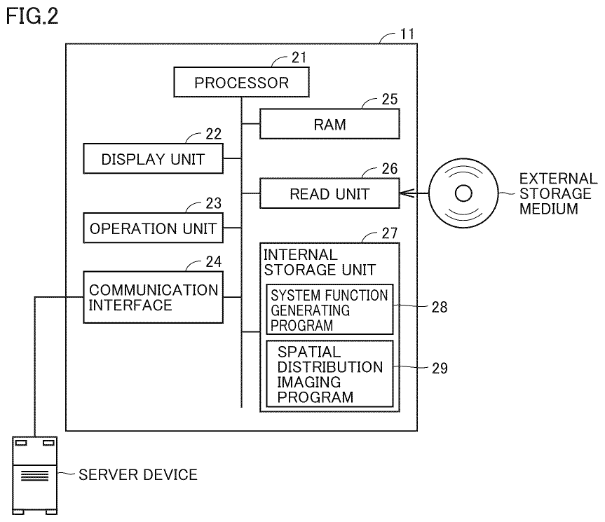

FIG. 2 is a diagram illustrating an example of a hardware configuration of information processing device 11. Information processing device 11 includes a processor 21, a RAM (random access memory) 25, a read unit 26, an internal storage unit 27, a display unit 22, an operation unit 23, and a communication interface 24.

Processor 21 is, for example, a CPU (Central Processing Unit) and performs computation.

RAM 25 stores temporary information generated as processor 21 performs computation. Processor 21 reads a program (including a system function generating program and a spatial distribution imaging program) stored in internal storage unit 27, loads the program in RAM 25, and executes the program.

Read unit 26 reads information recorded in an optical storage medium such as a CD-ROM (compact disk read only memory).

Internal storage unit 27 is, for example, a hard disk drive. Internal storage unit 27 stores a variety of types of programs such as a system function generating program and a spatial distribution imaging program, and a variety of types of data such as a numerical model for a calibration sample.

Display unit 22 is, for example, a liquid crystal display. Display unit 22 displays a screen generated in accordance with the computation by processor 21.

Operation unit 23 includes, for example, a keyboard, a mouse, and the like. Operation unit 23 receives an operation input by an operator.

Communication interface 24 communicates with an external device (for example, a server device) via a network.

The system function generating program includes a group of instructions for a process for generating a system function based on a measurement signal of a calibration sample. The spatial distribution imaging program includes a group of instructions for a process for imaging a spatial distribution of magnetic particles present in an examination sample such as a living body of a patient. These programs are recorded for example on an optical recording medium, read by read unit 26, and stored in internal storage unit 27. Alternatively, these programs may be downloaded from the server device through communication interface 24 and stored in internal storage unit 27.

Processor 21 stores a detection signal received from receiver 4. When the detection signal is measured as a voltage, and a field free region is present at a translational position n at an angle θⱼ, the detection signal has a k-th harmonic component Uₖ(rᵢ,θⱼ) represented by a convolution of a system function Sₖ(p) and a magnetic particle distribution c(p). p is a vector representing a three-dimensional position (x, y, z). The convolution operation is expressed by an expression indicated below, for example. The system function Sₖ(p) is determined by the magnetic particles' magnetization curve and an effect of characteristics of a device that calibrates the magnetic particle imaging system. In Expression (1), d³p represents dx×dy×dz.

$$\begin{matrix}[ Math . 1 ] & \\ {U}_{k} ( {r}_{i} , {θ}_{j} ) = \int {S}_{k} ( p ) \cdot c ( p ) {d}^{3} p & ( 1 )\end{matrix}$$

The system function Sₖ(p) is a transfer function when the magnetic particle distribution c(p) is an input and the k-th harmonic component Uₖ(rᵢ, θⱼ) of the detection signal is an output.

Using the k-th harmonic component Uₖ(rᵢ, θⱼ) of the detection signal and the magnetic particle distribution c(p) to calculate the system function Sₖ(p) will be referred to as a first deconvolution operation. The first deconvolution operation allows Sₖ(p) to be obtained from Uₖ(rᵢ,θⱼ) and the magnetic particle distribution c(p) without knowing characteristics of the system function Sₖ(p).

One example of the first deconvolution operation is a method for obtaining Sₖ(p) by subjecting to inverse Fourier transform a value obtained by dividing a Fourier transform value of Uₖ(rᵢ,θⱼ) by a Fourier transform value of c(p).

In the present embodiment, processor 21 performs a deconvolution operation using a data set of a first detection signal that is a detection signal as collected with a relative positional change between the calibration sample and the magnetic selection field. Hereinafter, the deconvolution operation performed using the data set of the first detection signal will be referred to as a first deconvolution operation. Herein, a “data set of the first detection signal” refers to a collection of data of the first detection signal as collected at a plurality of locations. Therefore, each data that is an element of the data set of the first detection signal is associated with a location at which the first detection signal is collected. For example, whenever the location is changed, data of the first detection signal associated with that location is collected. A collection of the data of the first detection signal thus collected for each location serves as the data set of the first detection signal. The first deconvolution operation may be performed using the data set of the first detection signal corresponding to all of the locations when scanning ends, or whenever the location to be scanned is changed, the first deconvolution operation may be sequentially performed using a data set of the first detection signal corresponding the locations before and after the location to be scanned is changed.

In doing so, for example, as a specific process, processor 21 may perform the first deconvolution operation by updating an expected system function so that a data set of a first expected detection signal obtained by a convolution operation on the calibration sample's magnetic particle distribution and the expected system function has a value as close as possible to the data set of the first detection signal. As one example, processor 21 may update the expected system function so that a sum of a square of an error between each element of the data set of the first expected detection signal and each element of the data set of the first detection signal decreases.

Using the detection signal's k-th harmonic component Uₖ(rᵢ,θⱼ) and the system function Sₖ(p) to calculate the magnetic particle distribution c(p) is referred to as a second deconvolution operation.

One example of the second deconvolution operation is a method for obtaining c(p) by subjecting to inverse Fourier transform a value obtained by dividing a Fourier transform value of Uₖ(rᵢ,θⱼ) by a Fourier transform value of Sₖ(p).

In the present embodiment, processor 21 performs a deconvolution operation using a data set of a second detection signal that is a detection signal collected with a relative positional change between the examination sample and the magnetic selection field. Hereinafter, a deconvolution operation performed using the data set of the second detection signal will be referred to as a second deconvolution operation. Herein, a “data set of the second detection signal” refers to a collection of a plurality of collected data of the second detection signal. Therefore, each data that is an element of the data set of the second detection signal is associated with a location at which the second detection signal is collected. For example, whenever the location is changed, data of the second detection signal associated with that location is collected. A collection of the data of the second detection signal thus collected for each location serves as the data set of the second detection signal. The second deconvolution operation may be performed using the data set of the second detection signal corresponding to all of the locations when scanning ends, or whenever the location to be scanned is changed, the second deconvolution operation may be sequentially performed using a data set of the second detection signal corresponding to the locations before and after the location to be scanned is changed. When this is done, the examination sample may be let stand in the examination region at one site or a plurality of sites, or may be moved with respect to the magnetic selection field.

Processor 21 may perform the second deconvolution operation by updating an expected magnetic particle distribution so that a data set of a second expected detection signal obtained by a convolution operation on the system function and the expected magnetic particle distribution has a value as close as possible to the data set of the second detection signal. As one example, processor 21 may update the expected magnetic particle distribution so that a sum of a square of an error between each element of the data set of the second detection signal and each element of the data set of the second expected detection signal decreases.

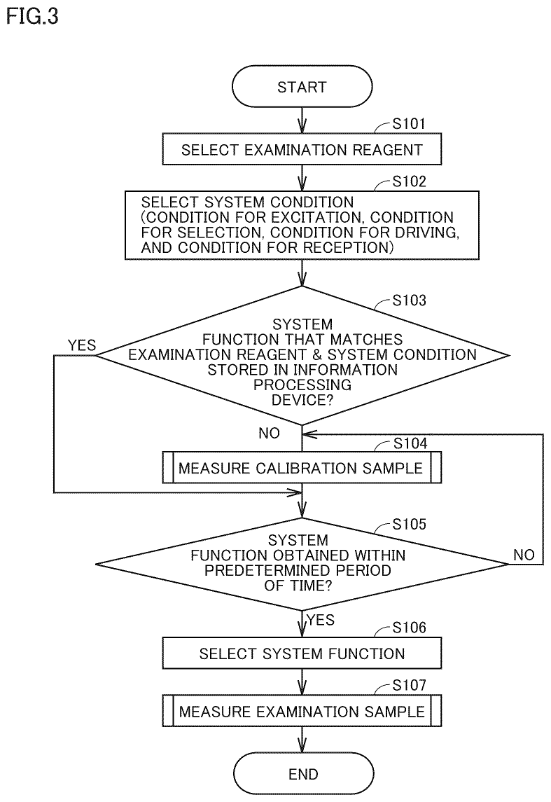

FIG. 3 is a flowchart of a procedure of a magnetic particle imaging method according to the embodiment.

In step S101, an examination reagent corresponding to a target substance to be imaged is selected.

In step S102, a system condition suitable for the analyte and the examination reagent is set. The examination reagent is obtained by modifying superparamagnetic particles with a protein or the like bound to the target substance by an antigen-antibody reaction. The examination reagent has a magnetization characteristic varying with the type of the examination reagent. Furthermore, when the magnetization characteristic varies, the system function also varies. Therefore, it is necessary to use a system function corresponding to the selected examination reagent. The magnetization characteristic is affected not only by characteristics of the magnetic particles per se, such as the size, distribution, etc. of the core particles of the magnetic particles, but also by effects of the surrounding environment, such as how a hydrodynamic particle diameter changes due to difference in type of antibody molecules modifying the magnetic particles, the viscosity in the vicinity of a lesion, etc.

The system condition representatively includes: an excitation intensity distribution, an excitation frequency and/or a similar condition for excitation; a distribution in strength of a magnetic selection field and/or a similar condition for selection; a condition for driving the magnetic selection field; and a distribution in sensitivity of a receiver coil, the filter's characteristics, the signal amplifier's characteristics and/or a similar condition for reception. The system condition is a system setting value that contributes to measurement signal strength.

In order to ensure that a reconstructed image obtained by spatial distribution imaging of magnetic particles is reliable, it is desirable to use a system function obtained under the same condition as diagnostic measurement (or examination sample measurement).

In step S103, whether a system function obtained under the same condition as a diagnostic measurement (or examination sample measurement) is stored in information processing device 11 is determined. If such a system function is not stored, the process proceeds to step S104.

In step S104, a calibration sample measurement is performed. Thus, the calibration sample measurement is performed before the diagnostic measurement (or examination sample).

In step S105, the timing at which the system function was obtained is determined. If the system function was not obtained within a predetermined period of time, the process returns to step S104. This is because even if a necessary system function has already been stored in information processing device 11, it is desirable to perform a periodic inspection to perform calibration sample measurement whenever the predetermined period of time elapses, as the magnetic particle imaging system's state changes with time. When the diagnostic measurement is performed using a system function with an examination reagent mismatched in type or a mismatched system condition, a reconstructed image obtained through spatial distribution imaging will be an image including an artifact, and the magnetic particle is also impaired in quantitativeness. This results in a negative effect on the diagnostic measurement.

In step S106, a system function is selected. Herein, for example, the latest system function is selected.

Once the system function is selected, a diagnostic measurement (or examination sample measurement) is performed in step S107. In the magnetic particle imaging method indicated in FIG. 3, initially, whether there is a system function matching a variety of types of conditions (e.g., the type of the examination reagent, the system condition, or the timing condition) is determined, and if there is no matching system function, a calibration sample measurement is performed before the examination sample measurement to obtain a system function matching the conditions.

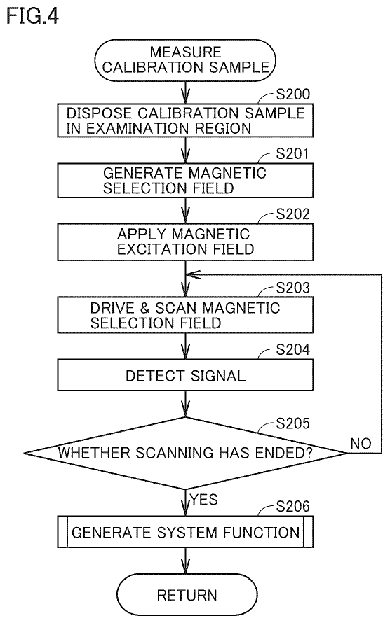

FIG. 4 is a flowchart of a procedure of calibration sample measurement in step S104 of FIG. 3.

Steps S201 to S206 in the flowchart shown in FIG. 4 are implemented by processor 21 executing a program loaded in RAM 25.

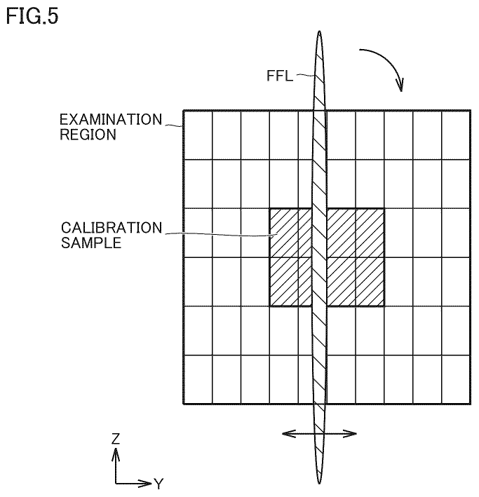

In step S200, a calibration sample is disposed in the examination region. FIG. 5 is a diagram illustrating an example of disposing the calibration sample. In this example, one cell in FIG. 5 corresponds to one pixel of a reconstructed image of a spatial distribution of the magnetic particles. The calibration sample with a size larger than that of the pixel of the reconstructed image suffices. In the example shown in FIG. 5, a field free line (FFL) is used as a field free region by way of example. The calibration sample is disposed for example substantially at the center of the examination region.

In step S201, processor 21 generates a command for controlling power supplied to the first electromagnet and the second electromagnet, and outputs the generated command to first power supply 7 for magnetic selection field and second power supply 8 for magnetic selection field. In response to the command, first power supply 7 for magnetic selection field and second power supply 8 for magnetic selection field start supplying power to the first electromagnet and the second electromagnet. As a result, a magnetic selection field is generated in the examination region.

In step S202, processor 21 generates a command for controlling power supplied to exciter 2, and outputs the generated command to power supply 5 for applying a magnetic excitation field. In response to the command, power supply 5 for applying a magnetic excitation field starts supplying power to exciter 2. As a result, an AC magnetic excitation field is applied to the analyte.

In step S203, processor 21 scans the magnetic selection field in the examination region by adjusting a balance between currents from first power supply 7 for magnetic selection field and second power supply 8 for magnetic selection field to the first electromagnet and the second electromagnet. For example, the magnetic selection field's position relative to a calibration sample let stand at one site in the examination region is changed. Furthermore, for the FFL, a rotational scan may be involved.

In step S204, receiver 4 receives as a detection signal a change in a magnetization moment of the magnetic particle excited by the magnetic excitation field. The received detection signal is input to information processing device 11 via noise removal filter 9 and signal amplifier 10.

In step S205, processor 21 determines whether scanning the magnetic selection field in the examination region has ended based on a preset ending condition. If the scanning has not ended, the process returns to step S203. When the scanning has ended, the process proceeds to step S206. For example, as an example of a case in which field free region FFR is a field free line (FFL), the scanning ends by rotating the FFL in a range of 0 degrees to 180 degrees with a specified angle increment and translating the FFL for each angle to positions in the entire range of the examination region. When field free region FFR has a different shape, the scan ending condition is different.

In step S206, processor 21 uses a detection signal set stored in step S204 to perform a process for generating a system function (or the first deconvolution operation).

The order of the generating the magnetic selection field in step S201 and the generating the magnetic excitation field in step S202 may be reversed. The order of the driving and scanning the magnetic selection field in step S203 and the detecting the signal in step S204 may be reversed.

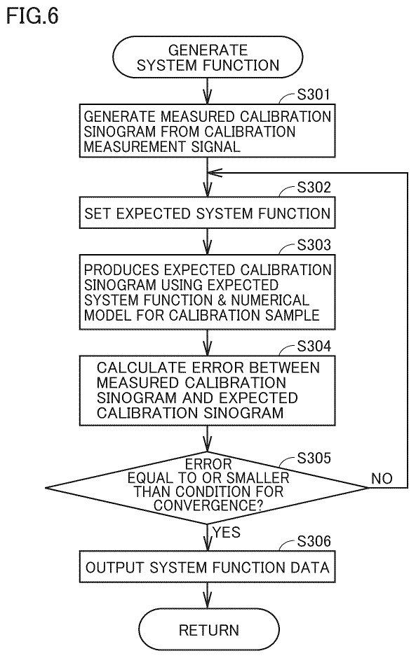

FIG. 6 is a flowchart of a procedure of a subroutine for generating a system function in step S206 of FIG. 4 (or the first deconvolution operation).

In step S301, processor 21 generates a measured calibration sinogram from the detection signal set and information indicating the field free region's scanning positions, as stored in step S204 of FIG. 4. The measured calibration sinogram is a map representing a k-th harmonic component Uₖ(r, θ) of the detection signal for an order k of a harmonic component, a translational position r, and an angle θ.

Uₖ(rᵢ, θⱼ) is represented by a convolution of the system function Sₖ(p) and the calibration sample's magnetic particle distribution c(p).

In step S302, processor 21 sets an expected system function S2ₖ(p). In step S302, for a first time, a predetermined initial value is set for the expected system function S2ₖ(p).

In step S303, processor 21 calculates a k-th harmonic component U2ₖ(r, θ) of an expected detection signal by a convolution operation on the expected system function S2ₖ(p) set in step S202 and the calibration sample's magnetic particle distribution c(p).

The calibration sample's magnetic particle distribution c(p) is represented by a numerical model representing the calibration sample's shape and magnetic particle concentration. When the calibration sample is magnetic particles uniformly filling a columnar space at a concentration ct, the numerical model is represented using a step function H(p), as indicated below. For example, when the calibration sample is in the form of a cylinder (a circle having a diameter R in the YZ plane and a length L in the X direction), the numerical model is represented by the following expression.

$$c ( r ) = ct \times [ H ( {( R / 2 )}^{2} - {( z - z 0 )}^{2} - {( y - y 0 )}^{2} ) \times H ( L / 2 - ( x - x 0 ) ) ] \qquad ( A 1 )$$

When the calibration sample is in the form of a quadrangular prism (having a length Lx in the X direction, a length Ly in the Y direction, and a length Lz in the Z direction), the numerical model is represented by the following expression.

$$c ( r ) = ct \times [ H ( Lx / 2 - ( x - x 0 ) ) \times H ( Ly / 2 - ( y - y 0 ) ) \times H ( Lz / 2 - ( z - z 0 ) ) ] \qquad ( A 2 )$$

In Expressions (A1) and (A2), x0, y0, and z0 are center coordinates of the calibration sample.

Processor 21 produces an expected calibration sinogram. The expected calibration sinogram is a map representing the k-th harmonic component U2ₖ(r, θ) of the expected detection signal for the order k of the harmonic component, translational position r, and angle θ.

In step S304, processor 21 calculates a sum E1 of a square of an error between each element of the measured calibration sinogram and each element of the expected calibration sinogram.

For example, when a tensor representing the expected system function S2ₖ(p) is represented by Sass and a tensor representing a numerical model of the magnetic particle distribution of the calibration sample is represented by Cmodel, a tensor Uass representing the expected calibration sinogram is represented by an expression indicated below. Sass has dimensions of k, rᵢ, θⱼ, x, y, and z. Cmodel has dimensions of x, y, and z. Uass has dimensions of k, rᵢ, and θⱼ.

$$Uass = Sass \cdot Cmodel \qquad ( B 1 )$$

When a tensor representing the measured calibration sinogram is represented by Ucal, E1 is represented by an expression indicated below. Ucal has dimensions of k, rᵢ, and θⱼ. The expression indicated below is a sum of a square of an error of each element of two tensors.

$$E 1 = {\vert Ucal - Uass \vert}^{2} \qquad ( B2 )$$

In step S305, processor 21 determines whether E1 is equal to or smaller than a predetermined condition for convergence. If E1 is equal to or smaller than a predetermined reference value, the process returns to step S302. If E1 exceeds the predetermined reference value, the process proceeds to step S306.

In step S302, processor 21 updates the expected system function S2ₖ(p). The processor updates the expected system function S2ₖ(p) by gradient descent, as indicated by an expression below. η is an acceleration coefficient for determining a rate applied to update the expected system function.

$$S {2}_{k} ( p ) = S {2}_{k} ( p ) - η ∇ E 2 ( S {2}_{k} ( p ) ) \qquad ( B 3 )$$

In step S306, processor 21 determines an expected system function S2ₖ(p) corresponding to an expected calibration sinogram satisfying the condition for convergence as the system function Sₖ(p).

While a system function generally has a smooth distribution, setting an expected system function S2ₖ(p) without a smooth distribution as it includes noise derives a result, that is, also gives noise to a spatial distribution image obtained as a result of spatial distribution imaging. Accordingly, the determined system function Sₖ(p) may be smoothed in a post processing, or a constraint may be imposed in a convergence calculation for determining the system function Sₖ(p).

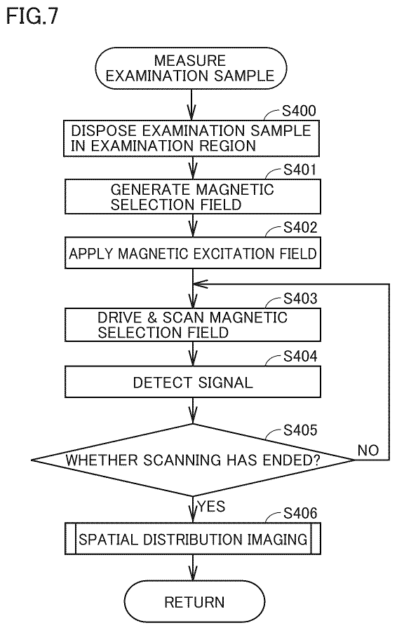

FIG. 7 is a flowchart of a procedure of diagnostic measurement (or examination sample measurement) in step S107 of FIG. 3.

Steps S401 to S406 in the flowchart shown in FIG. 7 are implemented by processor 21 executing a program loaded in RAM 25.

In step S400, an examination sample is disposed in an examination region. Steps S401 to S405 are the same as steps S201 to S205 of FIG. 4, and accordingly, will not be described repeatedly.

In step S406, processor 21 uses the detection signal set stored in step S404 to perform a spatial distribution imaging process (or the second deconvolution operation).

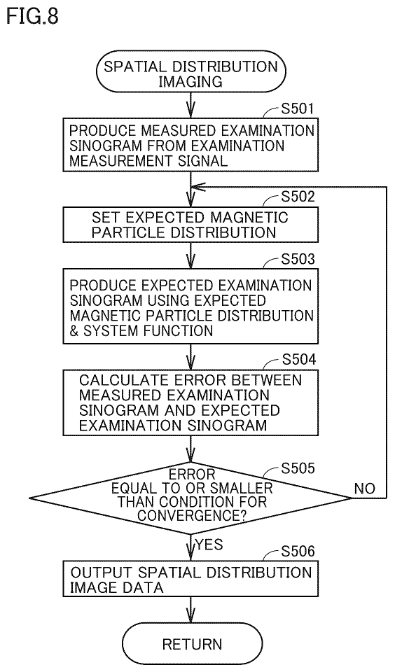

FIG. 8 is a flowchart of a procedure of the spatial distribution imaging process in step S406 of FIG. 7 (or the second deconvolution operation).

In step S501, processor 21 produces a measured examination sinogram from the detection signal set and information indicating the field free region's scanning positions, as stored in step S404 of FIG. 7. The measured examination sinogram is a map representing the k-th harmonic component Uₖ(r, θ) of the detection signal for the order k of the harmonic component, translational position r, and angle θ.

Uₖ(rᵢ,θⱼ) is represented by a convolution of the system function Sₖ(p) and the magnetic particle distribution c(p) of the examination sample.

In step S502, processor 21 sets an expected magnetic particle distribution c2(p). In step S502, for a first time, a predetermined initial value is set for the expected magnetic particle distribution c2(p).

In step S503, processor 21 calculates a k-th harmonic component U2ₖ(r, θ) of an expected detection signal by a convolution operation on the expected magnetic particle distribution c2(p) set in step S502 and the system function Sₖ(p).

Processor 21 produces an expected examination sinogram. The expected examination sinogram is a map representing the k-th harmonic component U2ₖ(r, θ) of the expected detection signal for the order k of the harmonic component, translational position r, and angle θ.

In step S504, processor 21 calculates a sum E2 of a square of an error between each element of the measured examination sinogram and each element of the expected examination sinogram.

For example, when a tensor representing the system function Sₖ(p) is represented by S and a tensor representing the expected magnetic particle distribution is represented by Cexp, a tensor Uexp representing the expected examination sinogram is represented by an expression indicated below. S has dimensions of k, rᵢ, θⱼ, x, y, and z. Cexp has dimensions of x, y, and z. Uexp has dimensions of k, rᵢ, and θⱼ.

$$Uexp = S \cdot Cexp \qquad ( C1 )$$

When a tensor representing the measured examination sinogram is represented by Uins, E2 is represented by an expression indicated below. Uins has dimensions of k, rᵢ, and θⱼ. The following expression is a sum of a square of an error of each element of two tensors.

$$E 2 = {\vert Uins - Uexp \vert}^{2} \qquad ( C2 )$$

In step S505, processor 21 determines whether E2 is equal to or smaller than a predetermined condition for convergence. If E2 is equal to or smaller than a predetermined reference value, the process returns to step S502. If E2 exceeds the predetermined reference value, the process proceeds to step S506.

In step SS02, processor 21 updates the expected magnetic particle distribution c2(p). Processor 21 updates the expected magnetic particle distribution c2(p) by gradient descent as follows:

$$c 2 ( p ) = c 2 ( p ) - η ∇ E 2 ( c 2 ( p ) ) \qquad ( C 3 )$$

In step S506, processor 21 determines the expected magnetic particle distribution c2(p) satisfying the condition for convergence as the magnetic particle distribution c(p). An image representing the magnetic particle distribution c(p) is spatial distribution imaging data, that is, a reconstructed image.

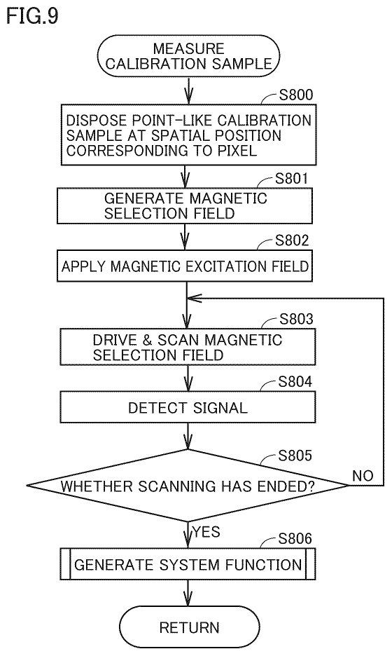

Hereinafter, PTL 1, and how PTL 1 and the present embodiment are different will be described. FIG. 9 is a flowchart of a procedure for measuring a calibration sample according to PTL 1.

The flowchart of FIG. 9 is different from the flowchart of FIG. 4 in that the flowchart of FIG. 9 includes steps S800 and S806 instead of steps S200 and S206.

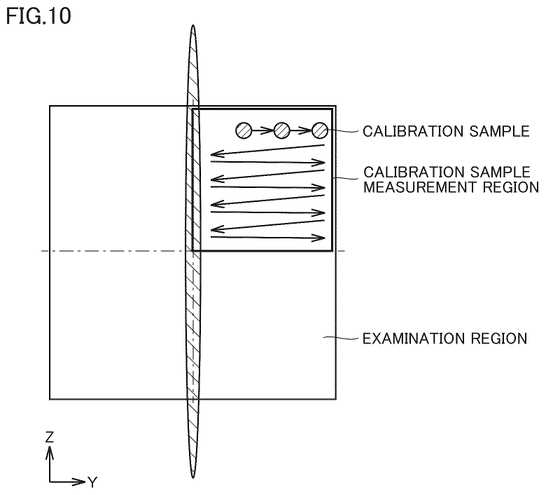

FIG. 10 is a diagram showing an example of disposing a calibration sample according to PTL 1. According to PTL 1, in step S801, a point-like calibration sample is disposed in an examination region at a spatial position corresponding to one pixel. The calibration sample is sequentially moved by a width corresponding to one pixel.

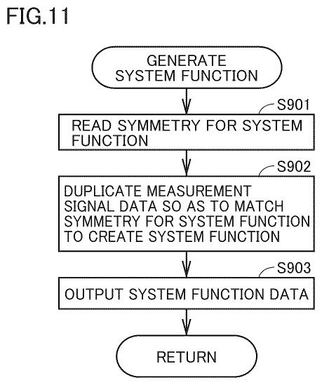

FIG. 11 is a flowchart of a procedure of a system function generating subroutine according to PTL 1.

In step S901, a symmetry for a system function is read. In step S902, data of a measurement signal (or a detection signal) is duplicated so as to match the symmetry for the system function to create the system function.

In step S903, system function data is output. In the present embodiment, a calibration sample's distribution is deconvoluted, and, in contrast to the method according to PTL 1, the calibration sample is not required to match in size to a size corresponding to a pixel of a reconstructed image, and the calibration sample can thus be larger in size than the pixel of the reconstructed image. The calibration sample large in size can be measured with a large measurement signal, and a sufficient SN ratio can be obtained even in a short measurement time. As a result, the calibration sample can be measured in a shorter period of time. Thus, in the present embodiment, a periodic inspection of a magnetic particle imaging system can be performed more frequently than conventional, and spatial distribution imaging is improved in image quality.

Furthermore, in the present embodiment, the calibration sample can be measured in the same procedure as diagnostic measurement (or measurement of an examination sample). In other words, it is unnecessary to move and dispose the calibration sample at a position corresponding to a pixel of a reconstructed image, and driving to change a relative positional relationship between the calibration sample and the magnetic selection field and thus scanning suffice. For example, when an FFL is used as a field free region, a calibration sample in an examination region may be measured while the FFL is translationally and rotationally scanned. This dispenses with mechanically scanning the calibration sample and thus allows calibration measurement to be done in a short period of time, and hence dispenses with a driving mechanism for mechanically scanning the calibration sample.

A reconstructed image is generally represented by pixels divided in the form of a lattice, and accordingly, in numerically modeling a calibration sample, using the calibration sample in the form of a quadrangular prism rather than a cylinder reduces a discretization error of an end portion of the calibration sample. The numerical modeling with a reduced error allows a system function to be generated with a reduced error and hence a spatial distribution image to be formed with a reduced error.

It should be understood that the presently disclosed embodiment is illustrative and non-restrictive in any respect. The scope of the present disclosure is defined by the terms of claims rather than the above description, and is intended to encompass any modification within the meaning and scope equivalent to the terms of the claims. It will be apparent to those skilled in the art that, of the contents described in the embodiment, those other than the matters recited in claim 1 are not essential.

### REFERENCE SIGNS LIST

2 exciter, 3a first selector, 3b second selector, 4 receiver, 5 power supply for applying a magnetic excitation field, 7 first power supply for generating and driving a magnetic selection field, 8 second power supply for generating and driving a magnetic selection field, 9 filter, 10 signal amplifier, 11 information processing device, 21 processor, 22 display unit, 23 operation unit, 24 communication interface, 25 RAM, 26 read unit, 27 internal storage unit.

1. A magnetic particle imaging system to image a spatial distribution of magnetic particles in an examination region, comprising:
a selector to generate a magnetic selection field having a spatial pattern of magnetic field strength to form in the examination region a first partial region having a low magnetic field strength and a second partial region having a higher magnetic field strength;
an exciter to provide a magnetic excitation field to change magnetization of the magnetic particles present in the magnetic selection field;
a receiver to receive as a detection signal a change in magnetization of the magnetic particles excited by the magnetic excitation field; and
a processor,
the detection signal being represented by a convolution of a spatial distribution of the magnetic particles and a system function,
the processor calculating the system function by a first deconvolution operation based on a data set of a first detection signal received by the receiver while a calibration sample is disposed in the examination region and a numerical model of a spatial distribution of magnetic particles included in the calibration sample,
the processor obtaining a spatial distribution of magnetic particles included in an examination sample by using the system function.

2. The magnetic particle imaging system according to claim 1, wherein the numerical model represents a shape of the calibration sample and a concentration of the magnetic particles included in the calibration sample.

3. The magnetic particle imaging system according to claim 1, wherein the calibration sample has a size larger than a size of a pixel of an image representing the obtained spatial distribution of the magnetic particles.

4. The magnetic particle imaging system according to claim 1, wherein
the calibration sample is a columnar space filled with magnetic particles, and
the processor uses a step function to generate the numerical model for the calibration sample.

5. The magnetic particle imaging system according to claim 1, wherein
the calibration sample is a space in a form of a quadrangular prism filled with magnetic particles, and
the processor uses a step function to generate the numerical model for the calibration sample.

6. The magnetic particle imaging system according to claim 1, wherein the processor performs the first deconvolution operation using a data set of a first detection signal collected while the magnetic selection field is positionally changed relative to the calibration sample when the calibration sample is let stand at one site in the examination region, the relatively positionally changing the magnetic selection field including rotationally scanning the magnetic selection field.

7. The magnetic particle imaging system according to claim 1, wherein the processor performs the first deconvolution operation by updating an expected system function so that a sum of a square of an error between each element of the data set of the first detection signal and each element of a data set of a first expected detection signal obtained by a convolution operation on the expected system function and the numerical model for the calibration sample decreases.

8. The magnetic particle imaging system according to claim 1, wherein the processor performs the second deconvolution operation by updating an expected magnetic particle distribution so that a sum of a square of an error between each element of the data set of the second detection signal and each element of a data set of a second expected detection signal obtained by a convolution operation on the system function calculated by a first deconvolution operation and the expected magnetic particle distribution decreases.

9. A magnetic particle imaging method for imaging a spatial distribution of magnetic particles in an examination region, comprising:
generating by a selector a magnetic selection field having a spatial pattern of magnetic field strength to form in the examination region a first partial region having a low magnetic field strength and a second partial region having a higher magnetic field strength;
providing by an exciter a magnetic excitation field to change magnetization of the magnetic particles present in the magnetic selection field; and
receiving by a receiver as a detection signal a change in magnetization of the magnetic particles excited by the magnetic excitation field, the detection signal being represented by a convolution of a spatial distribution of the magnetic particles and a system function,
the magnetic particle imaging method including:
calculating by a processor the system function by a first deconvolution operation based on a data set of a first detection signal received by the receiver while a calibration sample is disposed in the examination region and a numerical model of a spatial distribution of magnetic particles included in the calibration sample; and
obtaining by the processor a spatial distribution of magnetic particles included in an examination sample by using the system function.

10. A non-transitory computer-readable storage medium storing a magnetic particle imaging program for use in a magnetic particle imaging system to image a spatial distribution of magnetic particles in an examination region,
the magnetic particle imaging system generating a magnetic selection field having a spatial pattern of magnetic field strength to form in the examination region a first partial region having a low magnetic field strength and a second partial region having a higher magnetic field strength, the system providing a magnetic excitation field to change magnetization of the magnetic particles present in the magnetic selection field, the system receiving as a detection signal a change in magnetization of the magnetic particles excited by the magnetic excitation field, the magnetic particle imaging system comprising a processor, the detection signal being represented by a convolution of a spatial distribution of the magnetic particles and a system function,
the magnetic particle imaging program causing the processor to preform:
calculating the system function by a first deconvolution operation based on a data set of a first detection signal received as the detection signal while a calibration sample is disposed in the examination region and a numerical model of a spatial distribution of magnetic particles included in the calibration sample; and
obtaining a spatial distribution of magnetic particles included in an examination sample by using the system function.

11. The magnetic particle imaging system according to claim 1, wherein the processor obtains a spatial distribution of magnetic particles included in an examination sample by a second deconvolution operation based on a data set of a second detection signal received by the receiver while the examination sample is disposed in the examination region and the system function.

12. The magnetic particle imaging method according to claim 9, wherein obtaining a spatial distribution of magnetic particles includes obtaining by the processor the spatial distribution of magnetic particles included in an examination sample by a second deconvolution operation based on a data set of a second detection signal received by the receiver while the examination sample is disposed in the examination region and the system function.

13. The non-transitory computer-readable storage medium according to claim 10, wherein obtaining a spatial distribution of magnetic particles includes obtaining the spatial distribution of magnetic particles included in an examination sample by a second deconvolution operation based on a data set of a second detection signal received as the detection signal while the examination sample is disposed in the examination region and the system function.
